(19) United States
(12) Patent Application Publication
(10) Pub. No.: US 2024/0271483 A1
(43) Pub. Date: Aug. 15, 2024

(54) A WINDOW UNIT FOR A BUILDING OR STRUCTURE

(71) Applicant: CLEARVUE TECHNOLOGIES LTD, West Perth (AU)

(72) Inventor: Steven COONEN, Grass Valley, CA (US)

(73) Assignee: CLEARVUE TECHNOLOGIES LTD, West Perth (AU)

(21) Appl. No.: 18/041,326

(22) PCT Filed: Jan. 27, 2023
(86) PCT No.: PCT/AU2023/050045

§ 371 Date: Feb. 10, 2023

Related U.S. Application Data
(60) Provisional application No. 63/268,416, filed on Feb. 23, 2022.

(51) Int. Cl. E06B 9/24; E06B 3/663; E06B 3/667; E06B 3/67

(52) U.S. Cl. CPC E06B 9/24; E06B 3/66333; E06B 3/667; E06B 3/6722; E06B 2009/2464; E06B 2009/2476

(57) ABSTRACT

The present disclosure provides a window unit for a building or structure. The window unit comprises a first panel having an area transmissive for at least a portion of visible light. The first panel has opposite major surfaces. The window unit also comprises a second panel having an area transmissive for at least a portion of visible light. The window unit further comprises a spacer spacing the first panel from the second panel. At least one electric or electronic element is positioned within the spacer and indirectly or directly electrically coupled to at least electric component positioned within the window unit.

### CROSS REFERENCE TO RELATED APPLICATIONS

This application is a national stage filing under section 371 of International Application No. PCT/AU2023/050045, filed on Jan. 27, 2023, which claims priority benefit under 35 U.S. C. § 119 (e) of U.S. Provisional Application No. 63/268,416, filed Feb. 23, 2022. The entire contents of each application are incorporated herein by reference in their entireties.

### FIELD OF THE INVENTION

The present disclosure relates to a window unit for a building or structure and relates particularly to a window unit comprising electronic and/or electric components such as solar cells.

### BACKGROUND OF THE INVENTION

Buildings such as office towers, high-rise housings and hotels use large amounts of exterior window panelling and/or facades which incorporate glass panelling.

Such glass panelling receives large amounts of sunlight, which results in heating of interior spaces requiring the use of air conditioners. A large amount of energy is globally used to operate air conditioners.

PCT international applications numbers PCT/AU2012/000778, PCT/AU2012/000787 and PCT/AU2014/000814 (owned by the present applicant) disclose a spectrally selective panel that may be used as a windowpane and is transmissive for visible light, but has solar cells that absorb light, such as infrared radiation, to generate electricity.

The present invention provides further improvement.

### SUMMARY OF THE INVENTION

The present invention provides in a first aspect a window unit for a building or structure, the window unit comprising:
a first panel having an area transmissive for at least a portion of visible light, the first panel having opposite major surfaces;
a second panel having an area transmissive for at least a portion of visible light, the second panel having opposite major surfaces;
a spacer spacing the first panel from the second panel; and
at least one electric or electronic element positioned within the spacer and indirectly or directly electrically coupled to at least one electric component positioned within the window unit.

The window unit may comprise the at least one electric component. The at least one electric component may be positioned within a space between the first and second panels.

The at least one electric component may comprise a film or coating applied to a surface of the window unit.

In one embodiment the at least one electric component is provided in the form of at least one series of solar cells positioned along at least one edge of the first panel and facing a surface of the first panel.

The window unit may further comprise a frame having corner elements and side elements, each corner element being mechanically coupled to two side elements.

The spacer may be part of spacer structure which may surround an interior space between the first and second panels and may comprise corner spacer portions and elongated side spacer portions. The at least one electric or electronic element may be positioned within a corner spacer portion. The spacer structure may, together with a layer of butyl, form a primary seal of the window unit.

The window unit may comprise a first electric coupling and the at least one electric or electronic element may be indirectly or directly electrically coupled between the at least one series of solar cells or another electric component and the first electric coupling. The spacer may comprise the first electric coupling, such as an electric feedthrough (which may be hermetically sealed), a capacitive coupling, a plug, a lug or a socket or the like. Further, the frame may also comprise an electric coupling which may be coupled to the first electric coupling of the spacer. The first electric coupling of the spacer or the electrical coupling in the frame may comprise a wireless connection, such as a WIFI or Bluetooth connection or the like.

The at least one electric or electronic element positioned within the spacer may comprise, or may be provided in the form of, an electric lead and may or may not comprise further electric or electronic components, such as diodes and a battery or a capacitor arrangement for storing electricity generated by the at least one series of solar cells. The at least one electric or electronic element may also comprise electronic components such as a battery charge controller, a voltage regulator and further controller that control a function of the window unit.

The window unit may further comprise, and the at least one electric or electronic element positioned within the spacer may be coupled to, at least one of a suspended particle device, an electrochromic coating, an electro fluidic material, a liquid crystal device, a polymer-dispersed liquid crystal (PDLC) material and an electrophoretic material.

The first panel and second panel may be bonded together in a manner such that an airgap between the at least one series of solar cells with the spacer and the first and second panels is avoided and the solar cells with the spacer are sandwiched between the first and second panels. The first and second panels may be bonded together such that a laminated structure is formed. An adhesive may be used for bonding. In one embodiment the adhesive has a refractive index that at least approximates that of a material of the first and/or second component panel portions, which may for example be glass or a suitable polymeric material.

In a first specific embodiment the window unit comprises at least one series of solar cells positioned along edge portions of the first panel. The spacer may be positioned directly at an edge of the first panel and within a plane of the at least one series of solar cells. The first and second panels sandwiching the at least one series of solar cells and the spacer may be bonded using polyvinylbutyral (PVB). The at least one series of solar cells and the spacer may be sandwiched between sheets of PVB. In this embodiment bonding may be performed as follows. Initially a sheet of PVB may be positioned between the first panel and at least one series of solar cells with the spacer. Bonding of the at least one series of solar cells and the spacer to the first panel may be effected by applying heat to the sheet of the PVB material. An additional sheet of the PVB material may be positioned over the at least one series of solar cells and the spacer. Further (thicker) PVB sheets may be positioned on areas of the first panel at which no solar cells and no spacer is positioned. The second panel may then be positioned on exposed surfaces of the PVB sheet (s) and may be bonded to the exposed surfaces of the PVB sheet by the application of further heat such that a laminated structure is formed and the solar cells with the spacer are sandwiched between the first and second panels.

In an alternative second specific embodiment the spacer spaces the first and second panels form each other and at least one other electric component may be positioned between the first and second panels. The spacer may space the first and second panels from each other such that a gas-filled gap is formed between the first and second panels. In this case the spacer may be adhered between the first and second panel portions using an adhesive such as butyl.

The first panel may also comprise component panel portions which are laminated to each other using PVB as described above in the context of the first specific embodiment of the present invention. Further, the window unit may comprise at least one series of solar cells sandwiched between the first and second component panel portions as described above the context of the first specific embodiment of the present invention.

The first component panel portion may have a first major surface parallel to a first major surface of the second component panel portion, the first major surface of the second panel may have an area smaller than an area of the first major surface of the first component panel portion whereby the first and second component panel portions are arranged such that a projection of the first component panel portion along a surface normal extends beyond a circumference of the second component panel portion.

In one embodiment the window unit is a self-powered unit that does not necessarily require external wiring. In this embodiment the spacer may or may not comprise the electric coupling accessible from outside of the window unit. In this embodiment the window unit may for example comprise blinds which are powered using electricity generated by the at least one series of solar cells.

The at least one series of solar cells may comprise bifacial solar cells having opposite first and second surfaces, each having an area in which light can be absorbed to generate electricity, the solar cells being positioned such that in use the first surfaces are oriented to receive light from the light incident direction and the second surfaces receive light from an opposite direction. The solar cells of the at least one series of solar cells may be positioned in an overlapping relationship, such as in a shingle-like arrangement.

The first panel may also comprise a diffractive element and/or luminescent material in order to redirect or deflect incident infrared light towards edges of the first panel. The redirection or deflection of infrared radiation by the luminescent material or the diffractive element has the advantage that transmission of infrared radiation into buildings can be reduced, which consequently reduces overheating of spaces within the building and can reduce costs for air conditioning.

The at least one series of solar cells may be a first series of solar cells having active surfaces oriented substantially parallel to a major surface of the first panel. The first panel may have a plurality of edges and the window unit may comprise at least one second series of solar cells positioned along edge surfaces of the window unit, each solar cell of the second series of the solar cells facing an edge-surfaces and being oriented substantially perpendicular to the solar cells of the first series to receive light directed to edges of the first panel by the luminescent material or the diffractive element of the first panel.

The present invention provides in a second aspect a window unit for a building or structure, the window unit comprising:
a first panel having an area transmissive for at least a portion of visible light and comprising first and second component panel portions, the first component panel portion having a first major surface parallel to a first major surface of the second component panel portion, the first major surface of the second panel having an area smaller than an area of the first major surface of the first component panel portion whereby the first and second component panel portions are arranged such that a projection of the first major surface of the first component panel portion along a surface normal extends beyond a circumference of the second component panel portion.

The window unit may further comprise at least one series of solar cells positioned between the first and second component panel portions and oriented along an edge of the first component panel portion.

The window unit may also comprise a second panel having an area transmissive for at least a portion of visible light, and a spacer spacing the first panel from the second panel.

The spacer may be part of spacer structure which may surround an interior space between the first and second panels and may comprise corner elements and elongated side portions which each are coupled to two side portions. An electric or electronic element, such as an electric feedthrough, capacitive coupling, plug, lug or socket or the like may be positioned within a corner spacer element.

The invention will be more fully understood from the following description of specific embodiments of the invention. The description is provided with reference to the accompanying drawings.

### BRIEF DESCRIPTION OF THE DRAWINGS

FIG. 1 is a schematic top view of a window unit in accordance with an embodiment of the present invention; and

FIGS. 2-8 are schematic cross-sectional views of components of a window unit in accordance with embodiments of the present invention.

### DETAILED DESCRIPTION OF EMBODIMENTS

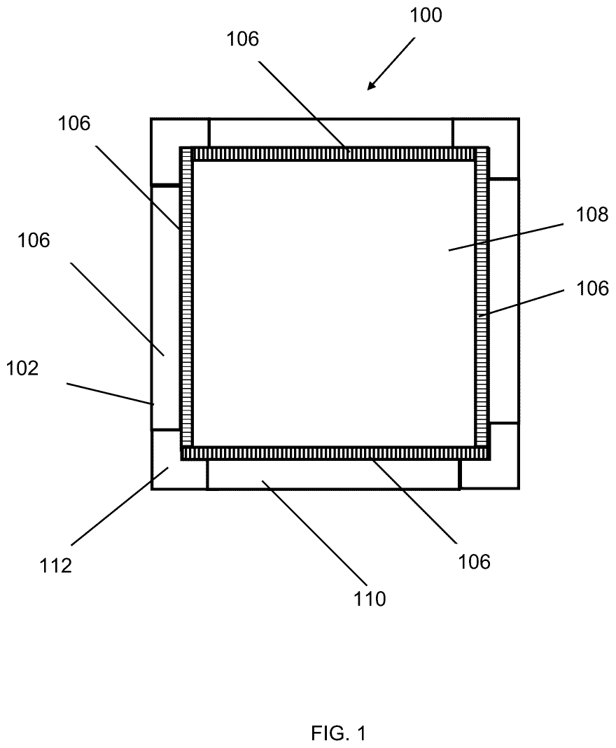

Referring initially to FIG. 1, a window unit according to an embodiment of the present invention is now described. The window unit 100 may for example be provided in the form of a window of a building, a sky light, a window of a car or any other structure that usually comprises windows.

The window unit 100 comprises a frame 102 having four corner elements 112 and four side elements 110. The window unit 100 further comprises a first panel 108 spaced apart from a second panel (not shown) by a spacer (also not shown). The first panel 108 and the second panel are transmissive for visible light. The window unit 100 also comprises four series of solar cells 106.

The window unit 100 may comprise further devices (not shown), which are operated using electricity generated by the series of solar cells 106. For example, the window unit 100 may incorporate devices or systems such as a blind, a curtain, an air damper, a fan, sensors or a pump. Further, the window unit 100 in accordance with embodiments of the present invention comprises components that regulate the transmissivity or another optical property of the window unit and may comprise for example a PDLC material, an electrochromic coating, an electro fluidic material, a liquid crystal device, a polymer-dispersed liquid crystal (PDLC) material or an electrophoretic material. The window unit comprises in one variation also electronic components required for operation and control of such devices and components. The electronic components are located in a spacer (not shown) which spaces the first panel 108 from the second panel.

The window unit 100 may be a self-powered unit and may not require external wiring. As required electric and electronic components are positioned within the spacer, it possible to provide and operate the window unit without the need for wiring.

In alternative embodiments the window unit may comprise external electric couplings and feedthroughs. Further, the frame of the window unit 100 may comprise an electric coupling for coupling an external battery for storing electricity generated by solar cells 110. For example, the frame may be arranged such that the external battery can be electrically and mechanically coupled to the window unit 100 using a snap-fit or the like.

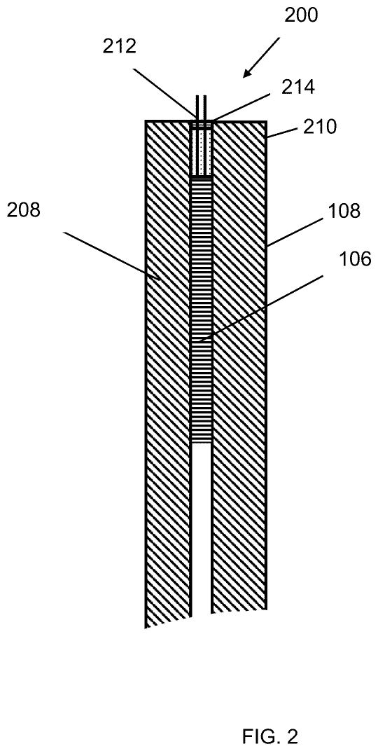

Referring now also to FIGS. 2-6, components of the window unit in accordance with embodiments of the present invention are now described. Like components are given like reference numerals.

FIG. 2 shows a cross-sectional view of a portion of components of a window unit 200 which comprises the first panel 108 and a second panel 208. Both the first and the second panels 108, 208 are transmissive for visible light. A series of solar cells 106 is positioned between the first panel 108 and the second panel 208. In this embodiment, the series of solar cells 106 comprises bifacial shingled solar cells having active front and rear surfaces. The first panel 108 and the second panel 208 are spaced apart by a spacer 210. The spacer 210 comprises an electric feedthrough 212 which is hermetically sealed. The electric feedthrough 212 is electrically coupled to the series of solar cells 106 using electric leads (not shown).

The spacer 210 surrounds an inner space between the first panel 108 and the second panel 208. The first and second panels 108, 208 are laminated together and the spacer 210 together with the series of solar cells 106 are sandwiched between the first panel 108 and the second panel 208. For bonding the series of solar cells 106 and the spacer 210 to panels 108, 208 initially a sheet of PVB is positioned between a first panel 108 and the series of solar cells 106 with the spacer 210. The PVB sheet is then exposed to heat such that bonding of the solar cells 106 to the first panel 108 is effected. A further sheet of the PVB material is then positioned over the series of solar cells 106 with the spacer 210 to protect and incapsulates the series of solar cells 106. In addition, further (thicker) PVB sheets are positioned on areas of the first panel 108 at which no solar cells or spacer are positioned. The second panel 208 is then bonded to the exposed surfaces of the PVB sheet again by the application of heat such that a laminated structure is formed and the solar cells 106 with the spacer 210 are sandwiched between the first and second panels 108, 208.

A layer of butyl 214 is applied over the spacer 210 to form a primary seal of the window unit 200.

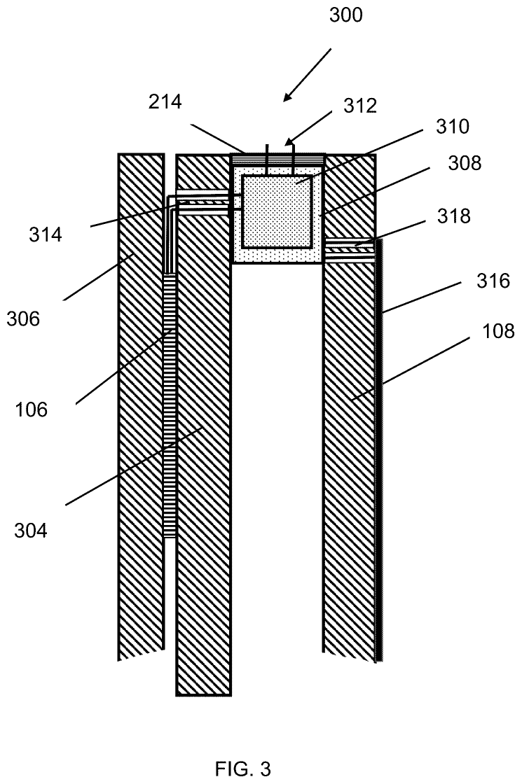

FIG. 3 shows a cross-sectional representation of components of a further variation 300 of the window unit in accordance with an embodiment of the present invention. Like components are given like reference numerals. In this embodiment the second panel comprises component panel portions 304, 306. The component panel 304 is spaced from the first panel 108 by a spacer 308. A gap is defied between the first panel 108 and the component panel 304 and the spacer 308. The gap may be filled with a gas, such as an inert gas. The spacer 308 surrounds the gap. The spacer 308 includes in this embodiment an electric component 310, which is coupled to a hermetically sealed feedthrough 312.

The series of solar cells 106 are sandwiched between the first and second component panel portions 304, 306. The first component panel portion 304 has through-holes 314 through which electric leads are directed. The electric leads electrically couple the solar cells 106 to the electric component 310 of the spacer 308. The first and second component panel portions 304, 306 are laminated together in the same manner as the first and second panels 108 and 208 of the window unit 200 described above with reference to FIG. 2 and described above. A layer of butyl 214 is applied over the spacer 310 to form a primary seal of the window unit.

The window unit 300 further comprises a polymer-dispersed liquid crystals (PDLC) switchable material 316. The PDLC material is positioned on an outside surface of the first panel 108 and electrically coupled to the electric or electronic component 310 by electric leads directed through through-holes 318. In this embodiment the electric or electronic component 310 comprises control electronics for controlling the PDLC material 316. A person skilled in the art will appreciate that the window unit 300 may alternatively also comprise components or switchable materials other than the PDLC materials.

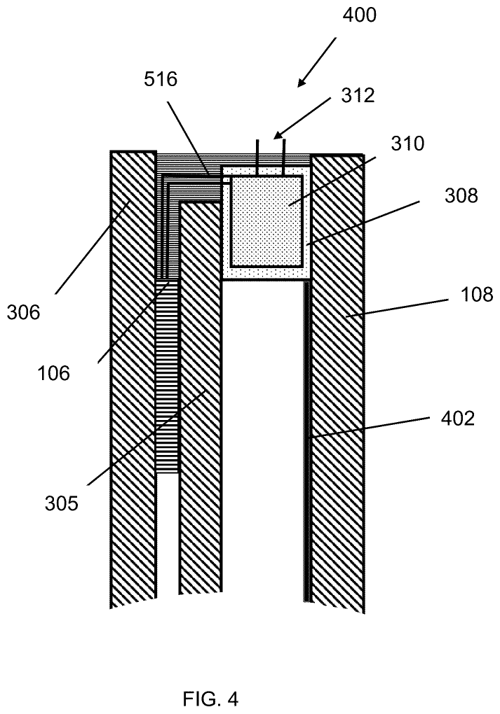

FIG. 4 shows a cross-sectional representation of components of a further variation 400 of the window unit in accordance with an embodiment of the present invention. Like components are given like reference numerals. The window unit 400 is similar to the window unit 300, but a first component panel portion 305 of the second panel has in this embodiment an extension which is smaller than both the extension of the second component panel portion 306 and the first panel 108. As can be seen in FIG. 4, an edge region of the second component panel portion 306 extends beyond an edge portion of the first component panel portion 305, which has the advantage that the electric leads can be guided to the spacer 308 (and the electric and electronic component 310 therein) within a projection of the circumference of the second component panel portion 306 and the first panel 108.

The window unit 400 further comprises a polymer-dispersed liquid crystals (PDLC) switchable material 402. The PDLC material 402 is in this example positioned on an inside surface of the first panel 108 and electrically coupled to the electric or electronic component 310 by electric leads (not shown). In this embodiment the electric or electronic component 310 comprises control electronics for controlling the PDLC material 402. A person skilled in the art will appreciate that the window unit 400 may alternatively also comprise components or switchable coatings other than the PDLC material, such as an electrochromic coating, an electro fluidic material, a liquid crystal device, a polymer-dispersed liquid crystal (PDLC) material or an electrophoretic material.

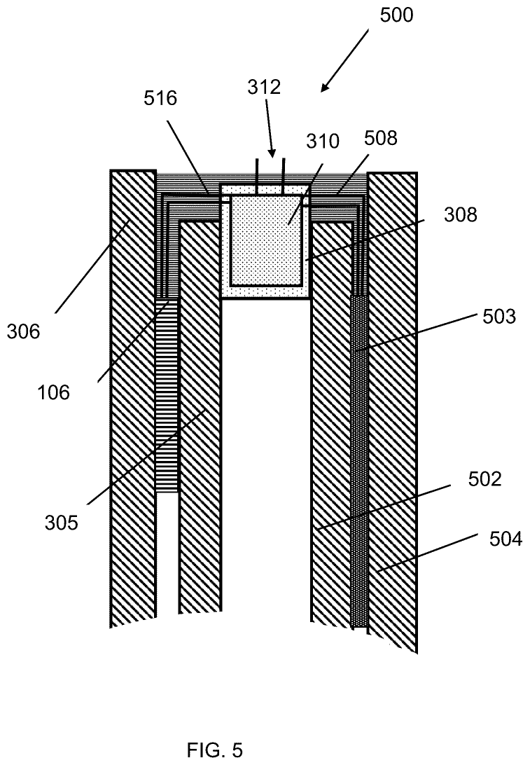

FIG. 5 shows a cross-sectional representation of components of another variation of the window unit in accordance with an embodiment of the present invention. Like components are given like reference numerals. The window unit 500 is similar to the window unit 400, but in this embodiment the second panel also comprises a first component panel 502 and a second component panel 504 which are laminated together. The window unit 500 comprises a suspended particle device 503 which is sandwiched between the first and second component panel portions 502, 504. A person skilled in the art that the window unit 500 may alternatively also comprise for example an electrochromic coating, an electro fluidic material, a liquid crystal device, a polymer-dispersed liquid crystal (PDLC) material and an electrophoretic material.

The first component panel portion 502 has in this embodiment a smaller major surface than both the second component panel portion 504. As can be seen in FIG. 5, an edge region of the second component panel portion 504 extends beyond an edge portion of the first component panel portion 502, and the electric leads 508 are guided from the suspended particle device 503 to the spacer 308 (and the electric and electronic component 310 therein) within a projection of the circumference of the second component panel portion 504.

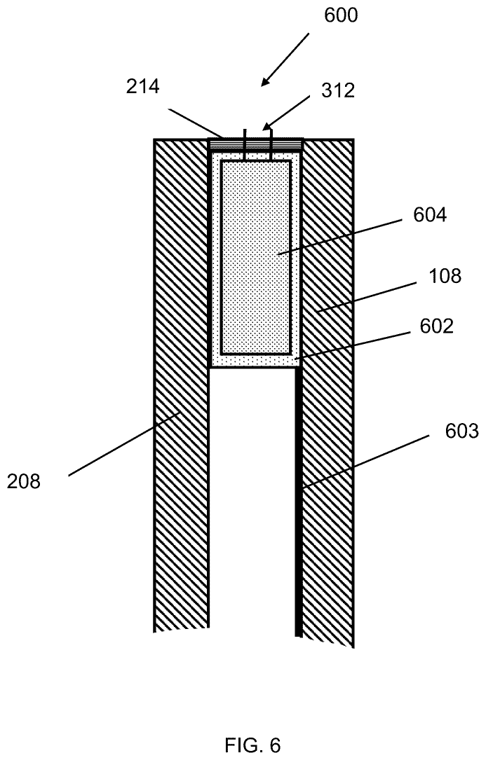

FIG. 6 shows a cross-sectional representation of components of a further variation 600 of the window unit in accordance with an embodiment of the present invention. Like components are given like reference numerals. The window unit comprises a first panel 108 spaced apart from a second panel 208 by the spacer 602. The window unit 600 does not comprise solar cells, but comprises in this embodiment a polymer-dispersed liquid crystals (PDLC) switchable material 603. The PDLC material 603 is electrically coupled to the electric or electronic component 604 positioned in the spacer 602. The electric or electronic component 604 includes control electronic for controlling the PDLC material 603. A person skilled in the art will appreciate that the window unit 600 may alternatively also comprise components or coatings other than the PDLC material 603, such as an electrochromic coating, an electro fluidic material, a liquid crystal device and an electrophoretic material.

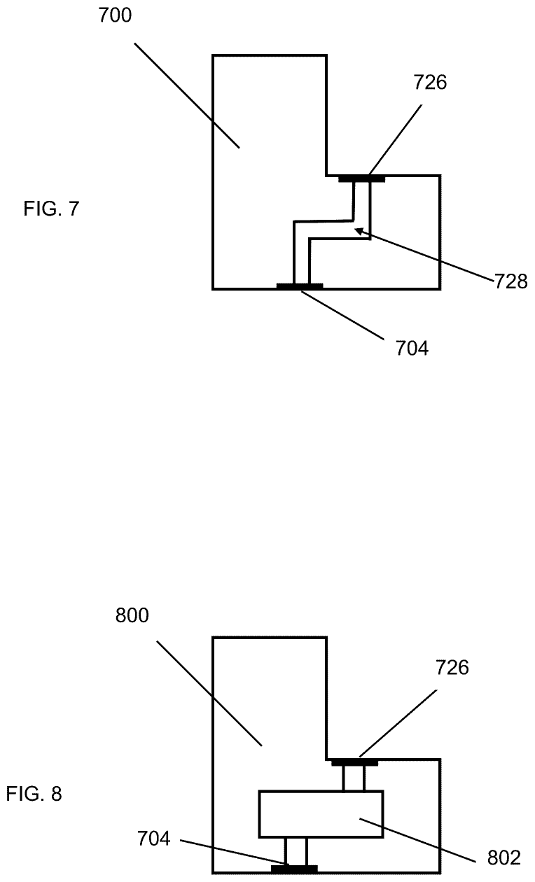

As mentioned above and described with reference to FIG. 1, the window unit 100 comprise a frame 102. The frame 102 may comprise corner elements or side elements with electric feedthroughs for coupling to the electric feedthrough of the spacers 210, 308, 602. FIG. 7 shows a schematic cross-sectional representation of a corner element 700 which may replace the corner element 112 shown in FIG. 1. The corner element 700 has an electric feedthrough with coupling 704, 726 and electric lead 728.

FIG. 8 shows a schematic cross-sectional representation of a further variation of the corner element of the frame. Like components are given like reference numerals. The corner element 800 shown in FIG. 8 may also replace the corner element 112 shown in FIG. 1. In this embodiment the corner element 800 also comprises an electric or electronic component 802, which may be a battery of may comprise control electronics.

The series of solar cells 106 may in any of the described embodiments be of any suitable type. For example, the solar cells may comprise different types of semiconductor material, such as one or more of Si, CdS, CdTe, GaAs, CIS or CIGS. Further, the solar cells may be positioned in a shingled arrangement and may comprise bifacial solar cells.

The electric and electronic components 310 in the window units 200, 300, 400 and 500 may also comprise diodes and battery or capacitor arrangements for storing electricity generated by the solar cells 106. Further, the electric and electronic components 310 may comprise a battery charge controller. Additionally or alternatively, the electronic and electronic components 310 may comprise voltage regulators which allow direct use of electricity generated by the solar cells 106 by other devices of the window unit.

Further, a person skilled in the art will appreciate that in in any of the described embodiments the spacer 308 may alternatively not comprise electronic components, by may simply comprise an electric component provided in the form of electric conductors for electric connection to the feedthrough. In addition, the spacer 308 may in a further variation not comprise a feedthrough, but may only house a battery and control electronics for controlling an another component or device of the window unit or storing electric energy received from an electric component of the window unit.

Any one of the first and second panels may in any of the described embodiments comprise a diffractive grating, luminescent material and/or the scattering material arranged to deflect incident infrared light preferentially towards an edge region of the panel. The window units may also comprise further solar cells facing an edge the panels positioned to receive the deflected incident infrared light.

A person skilled in the art will appreciate that the prior art to which reference is made does not constitute an admission that the referenced prior art is part of the common general knowledge in Australia or another country.

1. A window unit for a building or structure, the window unit comprising:
a first panel having an area transmissive for at least a portion of visible light, the first panel having opposite major surfaces;
a second panel having an area transmissive for at least a portion of visible light, the second panel having opposite major surfaces;
a spacer spacing the first panel from the second panel; and
at least one electric or electronic element positioned within the spacer and indirectly or directly electrically coupled to at least electric component positioned within the window unit.

2. The window unit of claim 1 comprising the at least one electric component.

3. The window unit of claim 2 wherein the at least one electric component is provided in the form of at least one series of solar cells positioned along at least one edge of the first panel.

4. The window unit of claim 1 wherein the spacer forms part of spacer structure which surrounds an interior space between the first and second panels.

5. The window unit of claim 4 wherein the at least one electric or electronic element is positioned within a corner spacer portion of the spacer structure.

6. The window unit of claim 1 comprising a first electric coupling and wherein the at least one electric or electronic element are indirectly or directly electrically coupled between the at least one electric component and the first electric coupling.

7. The window unit of claim 6 wherein the spacer comprises the electric first coupling.

8. The window unit of claim 6 wherein the spacer comprises an electric feedthrough.

9. The window unit of claim 1 wherein the at least one electric or electronic element comprises an electric lead.

10. The window unit of claim 1 wherein the at least one electric or electronic element comprises at least one of diodes, a battery and capacitor arrangement.

11. The window unit of claim 1 wherein the electric or electronic element comprises control electronics for controlling the at least one electric component.

12. The window unit of claim 1 wherein the at least one electric component comprises at least one of a suspended particle device, an electrochromic coating, an electro fluidic material, a liquid crystal device, a polymer-dispersed liquid crystal (PDLC) material and an electrophoretic material.

13. The window unit of claim 1 comprising at least one series of solar cells and wherein the first panel and second panels are bonded together in a manner such that an airgap between the at least one series of solar cells with the spacer and the first and second panels is avoided and the solar cells with the spacer are sandwiched between the first and second panels.

14. The window unit of claim 13 wherein the first and second panels are bonded together such that a laminated structure is formed.

15. The window unit of claim 1 wherein the window unit comprises at least one series of solar cells positioned along edge portions of the first panel and wherein the spacer is positioned directly at an edge of the first panel and within a plane of the at least one series of solar cells and wherein the first and second panels are laminated together.

16. The window unit of claim 1 wherein the spacer spaces the first and second panels form each other such as a gas-filled gap is formed between the first and second panels and wherein the first panel comprises component panel portions which are laminated.

17. The window unit of claim 16 comprising at least one series of solar cells sandwiched between the first and second component panel portions.

18. The window unit of claim 1 wherein the window unit is a self-powered unit that does not necessarily require external wiring.

19. The window unit of claim 1 comprising at least one series of solar cells which comprises bifacial solar cells having opposite first and second surfaces, each having an area in which light can be absorbed to generate electricity, the solar cells being positioned such that in use the first surfaces are oriented to receive light from the light incident direction and the second surfaces receive light from an opposite direction.

20. The window unit of claim 19 wherein the solar cells of the series of solar cells are positioned in an overlapping relationship, such as in a shingle-like arrangement.

21. The window unit of claim 1 wherein the first panel comprises first and second component panel portions and wherein the first component panel portion has a first major surface parallel to a first major surface of the second component panel portion, the first major surface of the second panel having an area smaller than an area of the first major surface of the first component panel portion whereby the first and second component panel portions are arranged such that a projection of the first component panel portion along a surface normal extends beyond a circumference of the second component panel portion.

22. A building or structure, the window unit comprising:
a first panel having an area transmissive for at least a portion of visible light and comprising first and second component panel portions, the first component panel portion having a first major surface parallel to a first major surface of the second component panel portion, the first major surface of the second panel having an area smaller than an area of the first major surface of the first component panel portion whereby the first and second component panel portions are arranged such that a projection of the first major surface of the first component panel portion along a surface normal extends beyond a circumference of the second component panel portion.

23. (canceled)

24. (canceled)

25. (canceled)
